(19) United States
(12) Patent Application Publication
(10) Pub. No.: US 2011/0234158 A1
(43) Pub. Date: Sep. 29, 2011

(54) DEVICE FOR CHARGING AN ENERGY STORE HEATING DEVICE, NOZZLE FOR SUCH A DEVICE AND METHOD FOR GENERATING HEAT ENERGY

(75) Inventors: Bernhard Artelsmair, Pettenbach (AT); Reinhold Fink, Waidhofen an der Ybbs (AT); Helmut Pfluegelmeier, Eferding (AT); Andreas Prielinger, Vorchdorf (AT); Guenther Sklarski, Sipbachzell (AT)

(73) Assignee: Fronius International GmbH, Pettenbach (AT)

(21) Appl. No.: 12/998,786

(22) PCT Filed: Dec. 18, 2009
(86) PCT No.: PCT/AT2009/000491

§ 371 Date: Jun. 2, 2011

(30) Foreign Application Priority Data
Dec. 19, 2008 (AT) A 1988/2008

(51) Int. Cl. H02J 7/00; H01L 35/30

(52) U.S. Cl. 320/109; 136/217; 136/205

(57) ABSTRACT

The invention relates to a charging device (1) for charging an energy store (2) with a power generation device (3), a charging device (4) and further components, wherein the power generation device (3) is formed by a heat source, comprising a least one burner (8) connected to a fuel supply line (10) and a thermoelement (9) and a burner (8), a heating device (31) and a nozzle (20) for such a charging device (1). According to the invention, a constant stable combustion and allowing a self-sustaining evaporation process can be achieved, wherein the power generation device (3), the charging device (4) and the further components are arranged in a common housing (5), wherein an evaporator (28) for the supplied fuel is arranged in the lower part of a burner housing (19) for the burner (8) and a back wall (14) for the housing (5) is designed as element for drawing off the heat.

The invention relates to a charging device for charging an energy storage, having an electricity-generating device, a charging unit and further components, wherein the electricity-generating device is formed by a heat source, which comprises at least one burner connected to a supply line for a fuel, and a thermoelement, and one side of the thermoelement is connected to the heat source, and the other side of the thermoelement is connected to at least one element for conducting away the heat.

The invention further relates to a burner for an electricity-generating device of such a charging device, having a burner housing.

The invention further relates to a heating means for a burner of an electricity-generating device of a charging device, which burner is arranged in a burner housing.

The invention further relates to a nozzle for a burner of an electricity-generating device of a charging device, which burner is arranged in a burner housing.

The invention finally relates to a method for generating heat energy in a heat source of an electricity-generating device of a charging device for charging an energy storage, wherein the heat energy is generated by a burner of the heat source, and the heat energy is converted into electricity at least partially by a thermoelement of the electricity-generating device.

Only burners for liquid fuels are known from the prior art for use in the temperature range up to 500° C., which burners atomise the fuel. To this end, the liquid fuel must be atomised correspondingly at a high pressure in order to obtain the fuel/air mixture required for combustion. The disadvantage of this is that, in order to generate the pressure, energy must constantly be supplied to maintain the combustion process.

DE 38 07 633 A1 describes a rechargeable battery which can be charged independently of the electric grid in that heat energy is converted directly into electrical energy using an electricity generator.

DE 195 29 564 A1 relates to a motor vehicle with built-in engine-independent heating, wherein electrical energy for supplying the components needed for the engine-independent heating is obtained using the Seebeck effect in order to relieve the car battery correspondingly.

Such a constant energy supply is problematic in particular in cases in which the burner is used in systems with an efficiency of less than 20%. If the burner is accordingly used as the basis for an electricity-generating device, it must be ensured that the already poor efficiency is not further reduced by its own high consumption.

Such an electricity-generating device is known from U.S. Pat. No. 7,180,264 B2 and is used for portable charging units. Consequently, the charging current for the batteries is generated by the electricity-generating device, wherein the electricity-generating device contains a tank with fuel, a burner, a thermoelement and a control device. The thermoelement generates an electrical voltage or electrical energy on the basis of its physical properties when it is connected to a consumer and thus an electric current flows. A prerequisite for the occurrence of the thermoelectric voltage is a certain temperature difference between one side and the side of the thermoelement opposite the same. To this end, one side of the thermoelement is heated with the aid of the burner, which burns the fuel from the tank, whereas the other side of the thermoelement is at ambient temperature, so that the temperature difference necessary for the thermoelectric voltage is ensured. In particular lithium ion and lithium polymer batteries with a maximum capacity of 0.5 Ampere hours (Ah) can be charged with this method. A battery or energy storage with a higher capacity, for example 30 Ah or higher, as is the case in an energy storage of a vehicle, in particular motor vehicle, cannot however be charged in a protective and effective manner. With the burner used, what is known as a screw burner, stable combustion is also not possible, so that the constant temperature difference necessary for effective electricity generation cannot be achieved.

The object of the present invention consists in the creation of an above-mentioned charging device for charging an energy storage, a burner, a heating means, a nozzle and a method for generating heat energy in a heat source of an electricity-generating device of a charging device, by means of which constantly stable combustion and self-maintenance of an evaporation process are possible. Disadvantages of the prior art should be avoided or at least reduced.

The object is achieved by an above-mentioned charging device for charging an energy storage, in which the electricity-generating device, the charging unit and the further components of the charging device are arranged in a common housing, wherein an evaporator for the supplied fuel is arranged in the lowest region of a burner housing of the burner, and a rear wall of the housing is formed as an element for conducting away the heat. The advantage of this and the features according to Claims 2 to 5 is that reliable protection from dirt is ensured, as everything is integrated in the device. Simple mounting on the element of the vehicle is likewise ensured by means of the rear wall of the charging device, the rear wall at the same time being configured as a cooling body. Optimum heat transfer between the element of the vehicle and the rear wall is thus ensured. Correspondingly, after the housing has been fastened, the rear wall and the element of the vehicle form a common element for conducting away the heat, as a result of which optimum heat dissipation and constant electricity generation is ensured. An essentially vertical arrangement of the burner is advantageous, as the structure of the burner is optimised for this position and thus optimum utilisation results.

The object is also achieved by an above-mentioned burner, wherein a plurality of regions are arranged one above the other in the burner housing, wherein an evaporator is arranged in the lowest region of the burner housing, followed by a mixing region, a combustion chamber and an exhaust chamber and an ignition device in one region. The advantage of this and at least of the features according to Claims 7 and 8 is that as a result an extremely compact structure, self-maintenance of the evaporation process and a stable and dynamic combustion process are possible, as a result of which the output range of the burner can be varied within a certain range. This is also achieved at least partially by the automatic addition of the air in the mixing chamber by a vacuum produced by the nozzle.

It is advantageous according to Claim 9 that the outflow speed of the fuel vapour is reduced and the said vapour is swirled so that uniform distribution takes place. The combustion is thereby stabilised extremely effectively.

At least one spacer ring and a ceramic filler body are advantageously arranged in the combustion chamber, wherein the spacer ring forms a chamber in the interior, and the ignition device is arranged in this chamber or in the exhaust chamber.

The measures according to Claim 11 are also advantageous, as a result of which it is not possible for exhaust gases to back up in the combustion chamber. This ensures a stable combustion process. The heat generated by the burner is likewise conducted to the thermoelement via the heat exchanger.

It is advantageous owing to the measures according to Claims 12 to 14 that an enlargement of the surface area is achieved by the filler body. The supplied fuel is thereby distributed over this surface and is thereby uniformly and completely evaporated, as this also has the effect of what is known as a demister. This means that the splashes arising when the fuel is supplied remain in the filler body and evaporate in turn. An optimum fuel/air mixture for an optimum flame without soot likewise results as a further consequence of the regulated fuel supply. Correspondingly, the temperature of the evaporator is also important, which results inter alia from the recirculation of the heat energy. This can also be ensured with a heating means, in particular during a starting phase.

To regulate the air supply into the mixing chamber, a bimetal flap can be arranged in the air supply tube.

It is also advantageous according to Claim 16, that the fuel vapour is purified so that the service life of the nozzle is increased. The purification region can for example be formed by at least one filter. Deposits in the channel of the nozzle are in particular effectively prevented.

The above-described burner is advantageously used in an above-described device for charging an energy storage.

The object is also achieved by an above-mentioned heating means, wherein a connection is provided to an evaporator of the burner, and the outer shape of the heating means is matched to the outer shape of the burner housing. The advantage of this and the features according to Claim 19 is that the evaporator is brought to the temperature required for a stable evaporation process, at least during the starting phase, so that a stable combustion process is correspondingly also possible. Active regulation during the evaporation process is likewise advantageously possible.

An insulation layer arranged between the evaporator and the coil body is also advantageous, as a result of which the heating means is protected from the high temperatures of the evaporator and the windings are not melted.

The above-described heating means is advantageously formed with one part of an above-described burner for use in an above-described device for charging an energy storage.

The object is also achieved by an above-mentioned nozzle for a burner of an electricity-generating device of a charging device, the shape of which is a disc and is matched to the shape of the burner housing, and has at least one channel, wherein the height of the disc and the shape of the channel are adapted to the output of the burner. Advantageous here and according to Claim 23 is that, owing to the very short channel, the latter cannot essentially become clogged, so that continuous bundling of the fuel vapour and of the pressure build-up in the evaporator is ensured.

The above-described nozzle is preferably integrated in an above-described burner.

The object is finally also achieved by an above-mentioned method for generating heat energy in a heat source in an electricity-generating device of a charging device for charging an energy storage, in which a fuel vapour is produced from a supplied fuel in an evaporator of the burner arranged in the lowest region of a burner housing of the burner, the fuel vapour is mixed to form a fuel mixture by adding air in a mixing region of the burner, and the said fuel mixture is burnt in a combustion chamber of the burner to generate the heat energy, wherein the heat energy is supplied to the thermoelement via an exhaust chamber. The advantages associated with this and with the features of Claims 26 to 28 can be found in the above description.

The above-described method for generating heat energy is preferably carried out with an above-described charging device, burner, heating means and nozzle.

The present invention and the advantageous thereof over the prior art are explained in more detail using the attached schematic drawings, which show an exemplary embodiment.

In the figures:

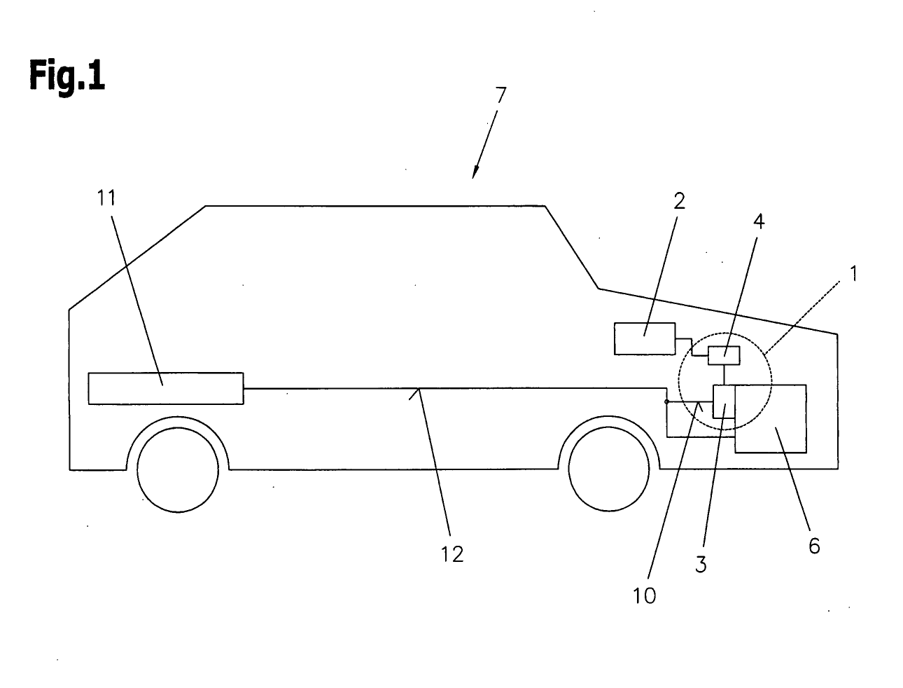

FIG. 1 shows a use of the charging device in a motor vehicle;

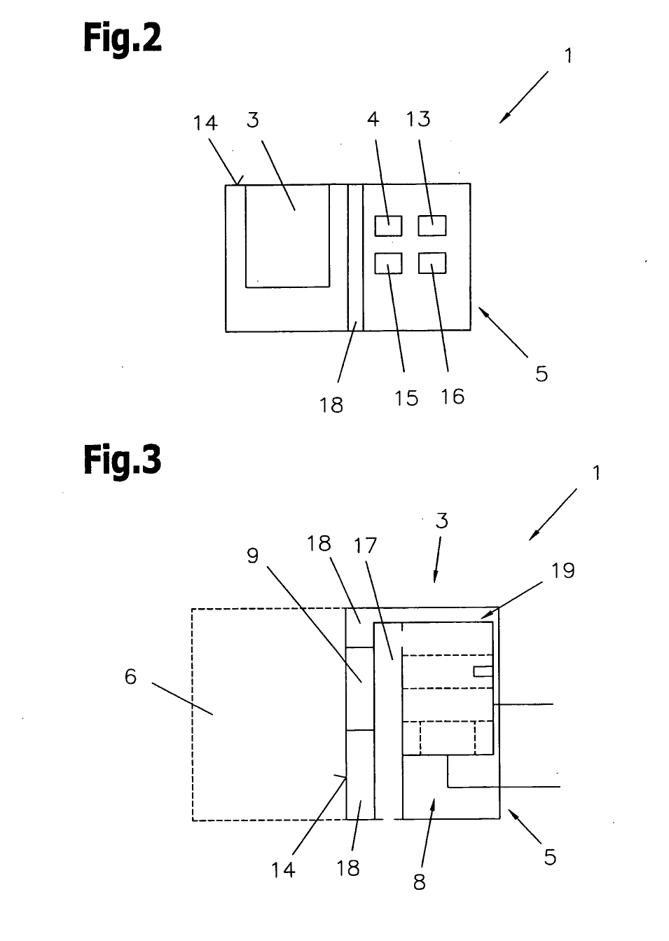

FIG. 2 shows a schematically illustrated charging device according to the invention;

FIG. 3 shows a sectional illustration of a schematically illustrated charging device in the mounted state;

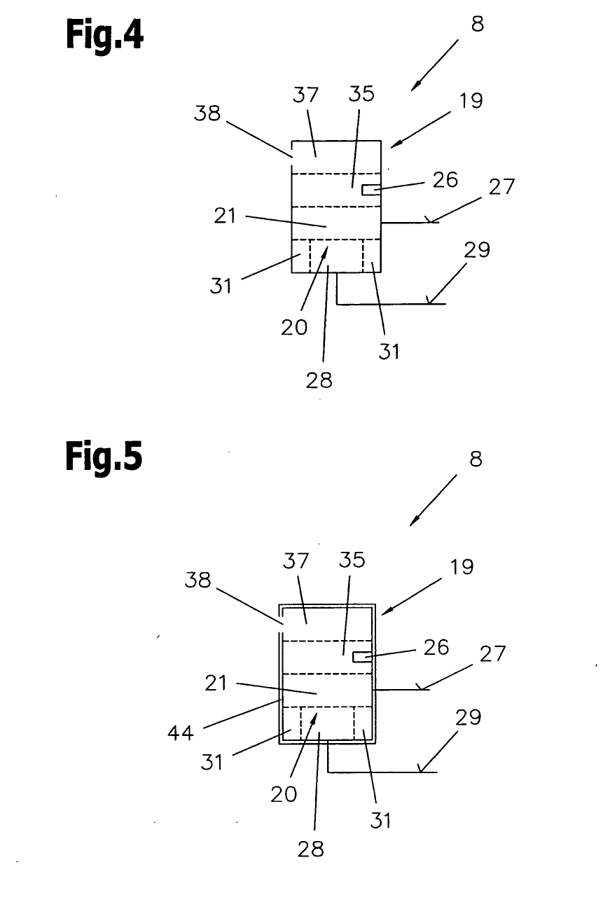

FIG. 4 shows a schematic illustration of a burner according to the invention of the charging device;

FIG. 5 shows a second embodiment of a burner of the charging device, schematically illustrated;

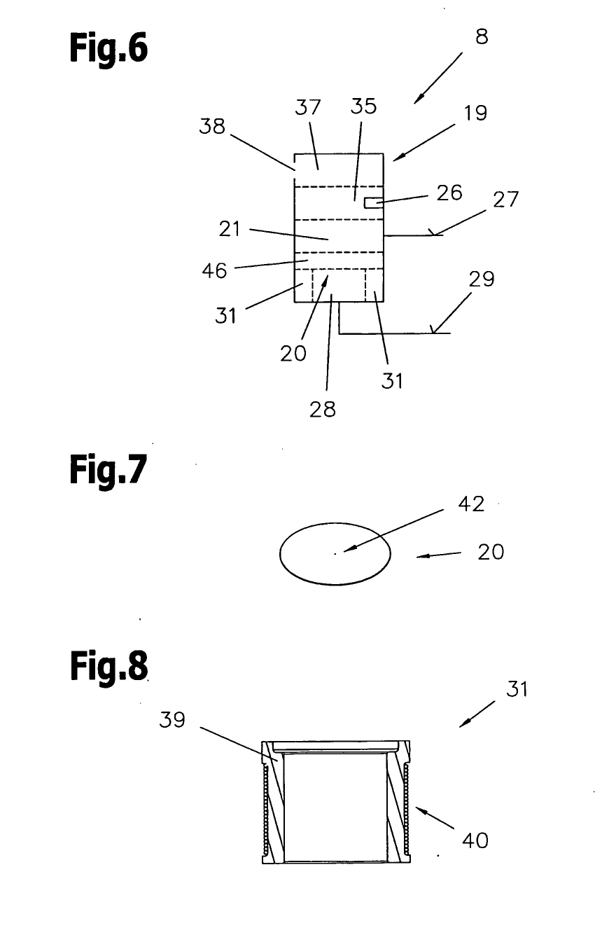

FIG. 6 shows a third embodiment of the burner of the charging device, schematically illustrated;

FIG. 7 shows a diagram of a nozzle according to the invention of the charging device; and

FIG. 8 shows an embodiment of a heating means according to the invention of the charging device.

To start, it is pointed out that the same parts of the exemplary embodiment are provided with the same reference symbols.

FIG. 1 shows a use of a charging device 1 or a charging system for charging an energy storage 2 of a vehicle 7 by way of example. The charging device 1 contains an electricity-generating device 3 and a charging unit 4. The electricity-generating device 3 and the charging unit 4 are preferably arranged in a housing 5, which is mounted on an element of the vehicle 7 (for example car, truck, motorcycle, ship etc.), which element is formed to conduct away the heat. The element for conducting away the heat is for example a metallic part of the vehicle 7, such as an engine block 6. The engine block 6 is therefore correspondingly formed as an element for conducting away the heat. The electricity-generating device 3 consists at least of a burner 8, a thermoelement 9 and at least one element for conducting away the heat, as is described and shown below in detail. The burner 8 is connected to a supply line 10 for a fuel of a tank 11 of the vehicle 7, which supply line branches off from a supply line 12 of the fuel for the engine in the engine compartment of the vehicle 7. The charging device 1 is also connected to a control device 13 as is also shown below. The energy storage 2 can thus be charged in that the output or electricity necessary for this is generated by the thermoelement 9, as long as a corresponding temperature difference exists between the two sides of the thermoelement 9. This temperature difference results from the fact that the thermoelement 9 is fixed between a so-called “hot side” and an opposite so-called “cold side”. Consequently, the “hot side” of the thermoelement 9 is fixed on the burner 8 and the “cold side” of the thermoelement 9 is fixed on the engine block 6, which acts as an element for conducting away the heat. The energy storage 2 of a vehicle 7 which has been switched off and is not in operation can thus be charged to maintain the charging level of the energy storage 2. The original charging level or charging state of the energy storage 2 can thus be maintained for a long time, as self-discharge of the energy storage 2 due to the removal of the stored energy by consumers can be counteracted. The functionality of the energy storage 2 is likewise in particular maintained by protective charging, so that for example the properties of a starter battery of the vehicle 7 which is used as an energy storage 2 are not adversely affected.

According to the invention, a charging device 1 is provided, in which all components necessary for the charging device 1 are integrated in a common housing 5. Simple mounting or subsequent installation into a vehicle 7 is thereby very easily possible. The schematic structure necessary for this charging device 1 and the function of the components are described in detail in the summary of the following FIGS. 2 to 8.

A charging device 1 and the components thereof are shown in FIGS. 2 and 3. It can be seen in particular from this that the housing 5 is formed in an essentially divided manner, wherein the electricity-generating device 3 is arranged in one part and the charging unit 4 and further components for the charging device 1, such as the control device 13, a fuel filter 15 and a fuel pump 16 are arranged in the further part. The division of the housing 5 can be realised by insulation 18, which is described in more detail below.

The electricity-generating device 3 contains a heat source consisting of the burner 8 and preferably a heat exchanger 17, and the thermoelement 9. The rear wall 14 of the housing 5 forms the “cold side” and the heat exchanger 17 forms the “hot side” of the thermoelement 9, which is preferably connected directly to the said components. Accordingly, the “hot side” is heated with a corresponding heat energy by means of the heat exchanger 17, wherein the heat energy which cannot be utilised by the thermoelement 9 is conducted away via the rear wall 14 and subsequently via the engine block 6 acting as the element for conducting away the heat. The rear wall 14 is also configured as a cooling body and consequently also already as an element for conducting away the heat, so that the charging device 1 can operate independently of the engine block 6. The rear wall 14 is however preferably mounted on the engine block 6, so that a common element for conducting away the heat is formed by the rear wall 14 and the engine block 6 and the possible operating life of the charging device 1 is increased.

The heat energy necessary for electricity generation by means of the thermoelement 9 is generated by means of the burner 8, which burns the fuel and is coupled to the heat exchanger 17. This heat energy formed in the burner 8 is composed of exhaust gas heat, heat radiation and heat transfer by mechanical contact. The heat energy is determined by the energy throughput or turnover which depends essentially on the quantity of fuel supplied. The exhaust gas heat is utilised in such a manner that the hot exhaust gases arising during the combustion of the fuel in the burner 8 are conducted into the upper part of the heat exchanger 17 and correspondingly conducted out of the housing 5 in the lower part. The heat exchanger 17 and consequently the “hot side” of the thermoelement 9 is therefore heated thereby. The heat radiation and the heat transfer through the mechanical contact between the burner 8 and the heat exchanger 17 should rather be considered as a supplementary side effect. The reason for this is that this type of heat energy is used primarily for self-maintenance and stabilisation of the combustion process. To this end, the burner 8 has what is known as air gap insulation 44, which is formed by a chamber filled with air. This chamber is preferably formed by a hollow cylinder or a double-walled cylinder, as is shown in FIG. 5. Accordingly, the burner housing 19 is surrounded by the said hollow cylinder, and the air gap insulation 44 is formed between the hollow cylinder and the burner housing 19. The hollow cylinder is preferably fixed with webs to the burner housing 19 and also has the openings which the burner housing 19 has. This also means however that the burner 8 is fixed by the hollow cylinder in the housing 5 and is connected by means of the latter to the thermoelement 9 or by means of the heat exchanger 17 to the thermoelement 9. The air gap insulation 44 can also be formed in that the heat exchanger 17 is formed for receiving the burner 8 (not shown). The main part of the heat exchanger 17 is however concentrated on the part which is associated with the thermoelement 9. The burner 8 is preferably fixed in the heat exchanger 17 by means of a press fit, wherein the air gap insulation 44 is formed by retaining points between the heat exchanger 17 and the burner 8. The burner 8 is thus retained by the retaining points in the heat exchanger 17. The heat transfer through mechanical contact is therefore ensured despite the air gap insulation 44.

So that the heat energy composed of the exhaust gas heat, the heat radiation and the heat transfer through mechanical contact can be used even more efficiently for electricity generation, insulation 18 of the electricity-generating device 3 is provided. This prevents a loss of heat energy and ensures a constant temperature difference between the “hot side” and the “cold side” of the thermoelement 9.

To operate the burner 8 and therefore the electricity-generating device 3, it is necessary to supply the burner 8 with a fuel from the tank 11 of the vehicle 7. To this end, the housing 5 has a connection for the supply line 10, so that the fuel can be supplied to the burner 8 via the fuel pump 16 arranged in the housing 5. A fuel filter 15 can also optionally be integrated in the fuel supply, so that the combustion process is not adversely affected by dirt in the supplied fuel. The fuel supply or the fuel pump 16 is regulated by the control device 13, so that an optimum combustion process can take place in the burner 8. To this end, a flow sensor can for example be integrated in the fuel supply, which sensor supplies the control device 13 with the corresponding information. The control device 13 can however also obtain essential information from the output consumption of the fuel pump 16. The pressure at which the fuel is conveyed into the evaporator 28 of the burner 8 can be determined thereby. Of course, further sensors can be connected to the control device 13, by means of which sensors an optimal combustion process and therefore the optimal utilisation of the thermoelement 9 for electricity generation is made possible. These can be for example sensors for measuring various temperatures (element(s) for conducting away the heat, heat source, exhaust gas etc.), the current, voltage, pressure and the like. These sensors are connected to the control device 13 either directly or via a data bus. The electricity generated by the electricity-generating device 3 or by the thermoelement 9 can be supplied to the charging unit 4. The charging unit 4 is arranged in a part of the housing 5 which is situated outside the insulation 18. The charging unit 4 converts this electricity in such a manner that the energy storage 2 (outside the charging device 1) can be efficiently charged. To this end, the charging unit 4 is preferably connected correspondingly to the control device 13. As such a function of the charging unit 4 is known from the prior art, this is not described in any more detail. The insulation 18 is also used to protect the further components, in particular the charging unit 4, the control device 13 and the fuel pump 16 from overheating.

The charging device 1 only has to be connected to the engine block 6, the supply line 12 and the energy storage 2 during commissioning in the vehicle 7. Furthermore, the control device 13 can be connected to a control device of the vehicle 7. The rear wall 14 of the housing 5 is preferably fixed to the engine block 6 in such a manner that the burner 8 is aligned essentially vertically to the ground under the vehicle 7 and thus a stable combustion process can be ensured. For the connection to the energy storage 2, that is, the battery of the vehicle 7, a corresponding coupling or connector is preferably provided in the housing 5. This is configured in such a manner that the components in the interior of the housing 5 are protected from dirt and moisture. The cables must be routed from the coupling or connector of the charging device 1 to the energy storage 2 in such a manner that they do not affect the operation of the vehicle 7. The supply line 12 for the fuel, which is likewise connected to a connection provided on the housing 5, must also be routed in the same manner.

One of the main components of the charging device 1 is the burner 8, which is described in detail using FIGS. 4 to 6. This should be viewed at least together with FIG. 3. The individual described embodiments of the burner 8 can also be combined. From this the burner housing 19 can be seen, which has a plurality of regions arranged one above the other. The lowest region is formed by an evaporator 28, in which a filler body can be arranged. The evaporator 28 has a connection for a supply line 29 for the fuel. Above the evaporator 28 there is a mixing region 21, to which an air supply tube 27 is connected so that a fuel mixture can be formed. A nozzle 20 is arranged between the evaporator 28 and the mixing region 21. The combustion chamber 35, in which the fuel mixture is burnt and the ignition device 26 is preferably integrated, is situated above the mixing region 21. A screen is preferably arranged as the transition from the mixing region 21 to the combustion chamber 35. This transition is also configured in a leak-tight manner so that the fuel mixture can no longer be changed. The combustion chamber 35 further contains at least one spacer ring and at least one ceramic filler body which are held in position for example with a safety ring. An exhaust gas chamber 37 is arranged above the ceramic filler body or safety ring.

The burner housing 19 consists essentially of two bodies, which are however preferably manufactured from one part. Both bodies are constructed cylindrically, one body being formed by the evaporator 28 and the other body containing the regions above and constituting the outer shape of the burner housing 19. The cylindrical body of the evaporator 28 has a smaller diameter than the cylindrical body arranged above it. This is due to the fact that the evaporator 28 is connected to a heating means 31. The heating device 31 is preferably arranged around the evaporator 28 so that the burner housing 19 is then formed by a common cylinder. The outer shape of the heating means 31 is thus matched to the outer shape of the burner housing 19. The heating means 31 and the evaporator 28 likewise essentially form one unit. The heating means 31 can also be integrated in the evaporator 28. An extremely compact structure of the burner 8 therefore becomes possible. The diameter or height of the burner housing 19 preferably does not exceed a value of three or seven centimetres, this depending on the output of the burner 8. The function of the regions and the dependencies between the regions are unrestricted due to the compact structure, so that stable operation of the burner 8 is ensured.

The supply line 29 is connected to the fuel pump 16, which is in turn connected to the supply line 10, so that the fuel supplied via the supply line 10 passes into the evaporator 28 and is evaporated correspondingly. The evaporation is to be divided essentially into two phases, into a starting phase, which has a completely cooled burner 8 as its starting point, and an operating phase, which follows the starting phase as soon as a stable combustion process has become established. The heating means 31 is necessary for the starting phase, by means of which heating means the evaporator 28 and also the filler body in the evaporator 28 is heated from outside to a temperature of over 100° C. If this temperature is reached, the fuel supply is started, that is, the fuel pump 16 is activated. As soon as the fuel reaches the evaporator 28, it is evaporated essentially immediately. This is in particular due to the fact that the filler body, for example steel wool, increases the surface area of the evaporator 28. The filler body likewise causes a separation between a vapour phase and a liquid phase. The liquid fuel therefore wets the hot surface of the filler body on entry into the evaporator 28 (liquid phase) and is thereby correspondingly evaporated (vapour phase). The fuel is preferably supplied from below so that the evaporation takes place in the lower region of the filler body. The upper part of the filler body 30 slows the fuel vapour arising during evaporation of the fuel, which then collects in a gas chamber underneath the nozzle 20. The volume of the fuel vapour is correspondingly increased in the gas chamber by the continuous conveying of the fuel, for example at 5 to 20 ml per minute (depending on output). If a certain volume with a pressure resulting therefrom is reached, the fuel mixture exits from the nozzle 20 through a very small channel 42. The shape of the channel 42 or for example the diameter of a hole forming the channel 42 is adapted to the volume of the fuel vapour, which essentially also depends on the output of the burner 8. The diameter or shape of the channel 42 therefore preferably varies within a range between 0.02 mm to 0.15 mm, the height of the nozzle 20 formed as a disc also lying essentially within this range. The small height has the advantage that the deposition of dirt is prevented or impeded. For this reason, the nozzle 20 is also referred to as a focusing aperture or foil. The fuel vapour is bundled thereby and exits at a certain pressure from the nozzle 20 into a mixing chamber of the mixing region 21. Depending on the dimensions and output of the burner 8, a pressure of for example 30 bar or more can be produced for operation. The exiting fuel vapour is also referred to as a jet, which is mixed with air through at least one opening which connects the mixing chamber and an air chamber, so that a flammable fuel mixture is formed. The air is sucked through the openings by a vacuum produced by the jet, the air being conducted first via the air supply tube 27 into the connected air chamber and subsequently via the openings into the mixing chamber. For better mixing of the fuel mixture, a flow opening is arranged in the mixing region 21 above the mixing chamber. This accelerates the jet so that eddies are produced, from which better mixing results.

The flow opening arises essentially from the structure of the mixing region 21, which has a narrowed portion in the centre of the mixing region 21. To this end, the mixing region 21 has the shape of an hourglass or the mixing region 21 contains a component with the shape of an hourglass. The narrowed portion is surrounded by the air chamber, that is, the air chamber is arranged in the outer region of the mixing region 21, the mixing chamber forming the lower part of the hourglass. The upper part of the hourglass is used to distribute the fuel mixture, as is described in more detail below. The narrowed portion in the centre of the mixing region 21 however also results in the channel 42 or the hole of the nozzle 20 and the flow opening being arranged in alignment so that the fuel vapour can be conducted into the combustion chamber 35 without any obstacles.

So that the fuel mixture flowing out can be used in the combustion chamber 35 for a stable combustion process, a screen is provided in the first step. This screen forms the transition between the mixing region 21 and the combustion chamber 35 and causes a reduction in the outflow speed of the fuel mixture. The slowed fuel mixture can thus be distributed uniformly over the entire cross section of the burner housing 19. To this end, a corresponding chamber is provided which forms part of the combustion chamber 35. The upper part of the hourglass, which collects part of the jet impinging on the screen, also contributes to the distribution, so that this part in the edge regions of the screen can flow through the latter into the combustion chamber 35. The screen can also have fan-shaped flow elements which are twisted in relation to the plane of the screen so that a radial deflection of the fuel mixture flowing through takes place. The jet is thus deflected via the fan-shaped flow elements, set in rotation and achieves better distribution.

The ceramic filler body, which rests for example on a spacer ring, can be arranged above the chamber in the combustion chamber 35. Accordingly, at least the spacer ring and the ceramic filler body are components of the combustion chamber 35. The spacer ring defines the volume of the chamber. The spacer ring can also be part of the hourglass of the mixing region 21. The ceramic filler body has the task inter alia of further promoting the mixing of the fuel mixture and stabilising the combustion over a wide dynamic range. This means that the fuel mixture does not flow out via the ceramic filler body, and the combustion process takes place exclusively in the combustion chamber 35. The combustion chamber 35 is therefore essentially defined between the screen and the upper edge of the ceramic filler body.

The combustion process is started with an ignition device 26, which consists of a spark plug and an ignition electronic system preferably integrated in the control device 13, in that the fuel mixture is ignited by a spark from the spark plug, a flame is formed and the fuel mixture is burnt in the combustion chamber 35. During the combustion process, heat energy is produced, which is necessary for the electricity-generating device 3. The spark plus is preferably arranged in the chamber described above, as the concentration of fuel vapour is high enough here to ignite the fuel vapour easily. The spark plug can however also be arranged in an exhaust gas chamber 37 above the ceramic filler body. The hot exhaust gases of the combustion process collect in the exhaust gas chamber 37 and are conducted via an outlet opening 38 in the burner housing 19 into the heat exchanger 17. The hot exhaust gases of the heat energy thus flow through the heat exchanger 17, and the “hot side” for the thermoelement 9 is formed. The exhaust gas chamber 37 is correspondingly the top region of the burner 8 in the burner housing 19.

Such a structure of the burner 8 can be optimised in that the latter is essentially arranged normally to a horizontal. The burner 8 should be aligned vertically during operation so that efficient utilisation is ensured.

If the vehicle 7 is parked on sloping ground, the burner 8 can be aligned with a corresponding device—which is likewise configured to conduct away the heat—between the rear wall 14 and the engine block 6. Such a structure of the burner 8 also means that at least some of the heat energy produced by the combustion process in the combustion chamber 35 is fed back into the evaporator 28. This is essentially due to the fact that the evaporator 28 is part of the burner housing 19 and is thus thermally coupled to the combustion chamber 35. The part of the burner housing 19 around the combustion chamber 35 is heated, and this heat is distributed over the entire burner housing 19 and drawn away from the part of the burner housing 19 which forms the evaporator 28. The filler body in the evaporator 28, which touches the burner housing 19, is in particular heated thereby. It is thus ensured that the evaporator 28 essentially always has the temperature to evaporate the liquid fuel during the operating phase. A temperature of more than 200° C. is usually necessary to do this.

The heating means 31 is switched off during the operating phase. This regulates the control device 13 correspondingly, which detects and evaluates at least the temperature of the evaporator 28 by means of corresponding temperature sensors (not shown). The evaporator 28 is therefore formed as a part of the burner housing 19 for self-maintenance of the evaporation process. Of course, the heating means 31 can also be activated during the operating phase, in particular if the recovery of heat is not sufficient, which is detected by means of the temperature sensors. This can be the case for example if the quantity of the fuel supply must be increased to increase the output of the charging unit 4. As the recirculation of the heat for self-maintenance of the evaporation process via the burner housing 19 is rather slow, brief activation of the heating means 31 is necessary. The heating means 31 can also have an influence on the regulation of the evaporation process and therefore on the combustion process, in that the jet is changed, as a result of which the addition of air and thus also the fuel mixture changes.

The heating means 31 is preferably configured as an induction heating system. In this case, the heating means 31 is formed from a roll-shaped coil body 39 on which a winding 40 is arranged, as shown in FIG. 8. The evaporator 28 forms the core of the induction heating system. To heat the evaporator 28, a high-frequency alternating current is applied to the winding 40 by the control device 13 and the part of the burner housing 19 which forms the evaporator 28 is heated by means of induced eddy currents in such a manner that the liquid fuel is evaporated. The coil body 39 is preferably manufactured from a material which is permeable for a magnetic field and at the same time thermally insulating. For example, plastics have these properties. Air gap insulation can also be arranged between the evaporator 28 and the coil body 39, which forms an insulation layer so that the windings 40 are not overheated. The heating means 31 acts mainly to heat the evaporator 28 during the starting phase and to insulate the evaporator 28. The thermal insulation prevents the evaporator 28 from emitting heat, so that the latter always has a constant temperature for a stable evaporation process. This is the basic requirement for a stable combustion process.

The corresponding configuration of the regions of the burner 8 for a stable combustion process have already been discussed but are described again in detail below. A stable combustion process is based essentially on a stable flame. This in turn requires a corresponding fuel mixture, that is, the correct ratio of fuel to air. This ratio is regulated in the charging device 1 according to the invention by the fuel supply, in that more or less is evaporated in the evaporator 28 corresponding to the amount of fuel delivered. In turn a higher or lower pressure of the fuel vapour results, on which the vacuum produced by the jet depends. As the vacuum is responsible for the addition of air, the addition of air can be attributed to the fuel supply. In the next step it is necessary for the fuel mixture to be mixed virtually uniformly essentially over the entire cross section of the burner housing 19, so that a stable, blue flame necessary for the combustion process results. This is necessary in order that the fuel mixture is burnt completely and no soot is formed, so that a long service life of the charging device 1 is ensured.

The main part of the mixing takes place in the chamber of the combustion chamber 35 and is completed in the ceramic filler body of the combustion chamber 35. The fuel mixture is flammable in the chamber and in the ceramic filler body, so that at least one flame is ignited by corresponding activation of the spark plug. The main flame is what is known as an oxidation flame, which burns both in the chamber and in the ceramic filler body. What is known as a secondary flame, which is also referred to as a reduction flame, also burns in the chamber. The reduction flame does not carry out complete combustion, as the fuel mixture in this region is not yet optimally mixed, because the jet enters the chamber here. As the reduction flame therefore burns below the ceramic filler body, the soot arising in the process is in turn completely burnt by the oxidation flame burning above it. Overall, complete combustion without formation of soot results. Such a compromise of the presence of a reduction flame and an oxidation flame is however accepted in favour of the installation size of the burner 8 and the simple, essentially passive and automatic production of the fuel mixture. Complete combustion is preferably also supported in that platinum is added to the ceramic filler body, as a result of which the latter becomes catalytically active and improves the combustion process correspondingly.

As already mentioned, the jet formed from the fuel vapour has essential importance for a stable combustion process. The corresponding factors which influence the jet must therefore also be taken into account. This is primarily the nozzle 20 which forms the jet on the basis of the channel 42 or hole. This also means however that the fuel vapour may only exit through the channel 42. The nozzle 20 accordingly also has the task of sealing off the mixing chamber from the evaporator 28, so that the fuel vapour can only exit through the channel 42 in a bundled manner. The shape of the nozzle 20 is accordingly matched to the shape of the burner housing 19. Depending on the size of the burner 8 or output of the charging device 1, the nozzle 20 can also have a plurality of channels 42 or holes, as a result of which the throughput of the jet is increased and therefore the thermal energy throughput or turnover is increased. This in turn results in a higher temperature of the combustion chamber 35.

As the channel 42 must withstand the pressure of the jet in order to ensure a constant jet, corresponding demands are made on the manufacture of the nozzle 20 and the channel 42. In principle, the channel 42 can be produced exactly according to shape and size requirements by methods such as erosion or lasering. The channel 42 can then also be coated, as a result of which the service life can be considerably increased by reducing the friction coefficient.

A monitoring system of the combustion process is preferably also provided in order to prevent a so-called “yellow” flame, which would cause soot and as a result of which a stable combustion process is not provided. This can for example be detected by applying a voltage to the spark plug at certain intervals. The voltage is increased correspondingly until an arc is formed. The voltage measured during arc formation is used as a measure for the ionisation of the fuel mixture. The distance between the poles of the spark plug is bridged by means of the ionised air in the exhaust gas chamber 37 or in the chamber, that is, the circuit is closed. The quality of the combustion can be deducted from the conductivity of the ionised air. If the fuel mixture is burning poorly (yellow flame), the air is less ionised and accordingly conducts more poorly, so that a smaller current results. On the other hand, during optimal combustion (blue flame), the fuel mixture is highly ionised and therefore very electrically conductive, resulting in a higher voltage needed to form the arc. Corresponding countermeasures are preferably introduced, for example the amount of fuel delivered is changed, using a reference table of the control device 13. This can likewise be used if the spark plug is arranged in the chamber 36, other voltage values being set while the effect stays the same.

A stable combustion process is however only useful for the charging device 1 if the temperature difference between the “hot side” and the “cold side” of the thermoelement 9 is sufficiently large. The control device 13 can monitor the temperature difference by detecting and evaluating the temperature of the engine block 6 and of the heat exchanger 17. If a temperature exceeds a limit value, the combustion process is adapted, for example stopped or regulated by means of the fuel supply or the heating means 31. It is thus ensured that the thermoelement 9, which is one of the essential components of the electricity-generating device 3, is not overheated and destroyed as a result. Effective charging of the energy storage 2 by the charging device 1 is thereby always ensured.

It may also be mentioned in general that it is taken into account in the overall structure of the charging device 1 that exhaust-gas and air paths are routed separately. This means that undesired mixing cannot occur in the region around the charging device 1, as a result of which mixing a flammable fuel mixture could be produced. This would only be the case if incomplete combustion took place, however. An unstructured foam can also be used as the ceramic filler body in the combustion chamber 35 and as the filler body 30 in the evaporator 28.

A further embodiment of the main component of the charging device 1, that is, the burner 8, is described below using FIG. 6. and also together with FIGS. 1 to 5. This means that, unless described otherwise, the function, structure etc. can be taken from there and/or combined.

The difference consists essentially in that what is known as a purification region 46 is integrated in the burner 8. This is arranged as a type of cover of the evaporator 28, so that the nozzle 20 is protected from dirt, as a result of which the service life of the nozzle 20 and thus the whole charging device 1 can be greatly increased. The purification region 46 can contain a separator and a spacer. The separator is configured similarly to the nozzle 20, wherein the number of recesses is a multiple, for example ten to twenty times, greater than the number of holes in the nozzle 20. The recesses have the task of filtering the evaporated fuel. The contaminants, such as tar, sometimes formed during the evaporation then accumulate in the recesses. Due to the large number of recesses, the deposits have essentially no effect on the amount of fuel allowed through. It would therefore be a very long time until all the recesses are clogged by the contaminants. The filtered fuel vapour collects in an intermediate chamber, which is formed by the spacer formed as a circular ring. The intermediate chamber is used essentially to build up the necessary pressure to form the jet and as a buffer for the fuel vapour. Such a structure of the purification region 46 means that the filtering can be made finer and adapted to the quality of the fuel. This can for example take place in such a manner that a plurality of separators are positioned one above the other. The path through the recesses is thereby lengthened, so that the contaminants can accumulate more easily. Furthermore, a filter can also be integrated in the purification region 46, which can for example be formed by fleece-like materials, so that even extremely fine contaminants are filtered out of the fuel vapour. This filter is positioned in the intermediate chamber and can be set by formation in filter stages. The purification region 46 is fixed in the same manner as the nozzle 20 or to the latter.

Furthermore, the air supply for the combustion process can be regulated by arranging a flap in the air supply tube 27. This is advantageous in particular during the starting process of the combustion process, as the combustion process is stabilised more quickly by reduction of the air supply. This can be compared with the function of what is known as a choke, as is generally known in vehicles 7. The flap is for example formed from bimetal, so that the air supply is regulated as a function of the temperature difference.

1-29. (canceled)

30. Arrangement of a charging device (1) in a vehicle (7), wherein the charging device (1) is used for charging an energy storage (2) of the vehicle (7) and has an electricity-generating device (3), a charging unit (4) and further components, wherein the electricity-generating device (3) is formed by a heat source, which comprises at least one burner (8) connected to a supply line (10) for a fuel, and a thermoelement (9), and one side of the thermoelement (9) is connected to the heat source, and the other side of the thermoelement (9) is connected to a rear wall (14) of the housing (5), wherein the electricity-generating device (3), the charging unit (4) and the further components are arranged in a common housing (5), wherein an evaporator (28) for the supplied fuel is arranged in the lowest region of a burner housing (19) of the burner (8), and wherein the rear wall (14) of the housing (5) is fixed to an engine block (6) of the vehicle (7) which is used to conduct away the heat.

31. Charging device (1) according to claim 30, wherein a sensor for detecting the temperature is integrated in the rear wall (14).

32. Charging device (1) according to claim 30, wherein the electricity-generating device (3) is arranged preferably separated from the further components in the housing (5) by insulation (18).

33. Charging device (1) according to claim 30, wherein the heat source is formed from a burner (8) and a heat exchanger (17).

34. Charging device (1) according to claim 33, wherein the burner (8) is arranged essentially vertically during operation.

35. Burner (8) for an electricity-generating device (3) of a charging device (1) having a burner housing (19) in which a plurality of regions are arranged one above the other, an evaporator (28) is arranged in the lowest region of the burner housing (19), followed by a mixing region (21), a combustion chamber (35) and an exhaust gas chamber (37), and having an ignition device (26) arranged in one region, wherein a ceramic filler body is arranged above a spacer ring in the combustion chamber (35) to ensure that the fuel mixture does not flow out via the ceramic filler body and the combustion process takes place exclusively in the combustion chamber (35), wherein the spacer ring forms a chamber in the interior and the ignition device (26) is arranged in this chamber or in the exhaust gas chamber (37).

36. Burner (8) according to claim 35, wherein the evaporator (28) is connected to the mixing region (21) by means of a nozzle (20), and the nozzle (20) is configured to supply a mixing chamber in the mixing region (21) with a fuel vapor produced in the evaporator (28).

37. Burner (8) according to claim 35, wherein the mixing region (21) is formed at least by an air chamber and a mixing chamber, and an air supply tube (27) is connected to the air chamber, wherein the air chamber and the mixing chamber are connected with at least one opening.

38. Burner (8) according to claim 35, wherein the mixing chamber is configured to produce a fuel mixture, and the mixing chamber is connected to the combustion chamber (35) via a flow opening and a screen.

39. Burner (8) according to claim 35, wherein the combustion chamber (35) is connected to the exhaust gas chamber (37) arranged in the upper part of the burner housing (19), and the exhaust gas chamber (37) is connected via an outlet opening (38) to a heat exchanger (17) for conducting at least some of the heat energy formed during combustion in the combustion chamber (35) to a thermoelement (9).

40. Burner (8) according to claim 35, wherein the burner housing (19) is configured for recirculating at least some of the heat energy to the evaporator (28).

41. Burner (8) according to claim 35, wherein a supply line (29) for regulated supply of a liquid fuel is connected to the evaporator (28), and a filler body is arranged in the evaporator (28).

42. Burner (8) according to claim 41, wherein the evaporator (28) is connected to a heating means (31).

43. Burner (8) according to claim 37, wherein a bimetal flap for regulating the supplied air is arranged in the air supply tube (27).

44. Burner (8) according to claim 36, wherein a purification region (46) for fuel vapor is arranged below the nozzle (20).

45. Burner (8) according to claim 35, wherein a heating means (31) is provided which is connected to the evaporator (28).

46. Burner (8) according to claim 45, wherein the heating means (31) is realized by an induction heating system having a coil body (39) provided with windings (40), the core of which coil body is formed by the evaporator (28).

47. Burner (8) according to claim 46, wherein an insulation layer is arranged between the evaporator (28) and the coil body (39).

48. Burner (8) according to claim 36, wherein the nozzle (20) is configured as a disc and is matched to the shape of the burner housing (19), and has at least one channel (42), wherein the height of the disc and the shape of the channel (42) are adapted to the output of the burner (8).

49. Burner (8) according to claim 48, wherein the at least one channel (42) is arranged in alignment with a flow opening in the mixing region (21).

50. Method for generating heat energy in a heat source of an electricity-generating device (3) of a charging device (1) for charging an energy storage (2) of a vehicle (7), wherein the heat energy is generated by a burner (8) of the heat source, and the heat energy is at least partially converted into electricity by a thermoelement (9) of the electricity-generating device (3), wherein, in an evaporator (28) of the burner (8), which evaporator is arranged in the lowest region of a burner housing (19) of the burner (8), a fuel vapor is produced from a supplied fuel, the fuel vapor is mixed to form a fuel mixture by adding air in a mixing region (21) of the burner (8), and the said mixture is burnt in a combustion chamber (35) of the burner (8) to generate heat energy, wherein the heat energy is supplied to one side of the thermoelement (9) via an exhaust gas chamber (37), and the other side of the thermoelement (9) is fixed to an engine block (6) of the vehicle (7).

51. Method according to claim 50, wherein at least some of the heat energy is fed back to the evaporator (28) via a burner housing (19) of the burner (8).

52. Method according to claim 50, wherein the fuel vapor is conducted at a pressure into the mixing region (21), wherein the air is automatically added by the pressure.

53. Method according to claim 50, wherein a heating means (31) is activated at least during a starting phase in order to produce the fuel vapor.
